(19) United States
(12) Patent Application Publication
(10) Pub. No.: US 2026/0101593 A1
(43) Pub. Date: Apr. 9, 2026

(54) METHOD OF MANUFACTURING POINT CONTACT SOLAR CELLS AND APPARATUS USING THE SAME

(71) Applicant: Terasolar Energy Materials Corp., Miaoli County (TW)

(72) Inventors: Pang-Hao Wu, Hsinchu County (TW); Shih-Cheng Lin, Hsinchu County (TW); Cheng-Syun Tang, Miaoli County (TW)

(73) Assignee: Terasolar Energy Materials Corp., Miaoli County (TW)

(21) Appl. No.: 19/063,356

(22) Filed: Feb. 26, 2025

(30) Foreign Application Priority Data
Oct. 8, 2024 (TW) 113138285

(51) Int. Cl. H10F 10/11; H10F 71/00; H10F 77/20; H10F 77/63

(52) U.S. Cl. CPC H10F 10/11; H10F 71/135; H10F 77/219; H10F 77/68

(57) ABSTRACT

An apparatus of manufacturing high-efficiency solar cells by reducing contact resistance and forming point contacts is disclosed. The apparatus includes a carrying device configured to support a solar cell, a conducting module electrically connected to the solar cell optionally, a pulsed power supply used to provide a high frequency pulsed voltage that is a reverse bias voltage and has a frequency of about 1 kHz to 10 MHz and a duty cycle of about 5% to 95%, and a light source. As the pulsed power supply applies the high frequency pulsed voltage to the solar cell via the conducting module, the light source illuminates the solar cell at a power density of 10 W/m² above and scans the solar cell. Thereby discontinuous conductive regions are formed in the solar cell.

### CROSS REFERENCE TO RELATED APPLICATION

This application claims the benefit of priority under 35 U.S.C § 120 of Taiwan Patent Application Serial No. 113138285 filed on Oct. 9, 2024, the content of which is relied upon and incorporated herein by reference in its entirety.

### BACKGROUND OF THE INVENTION

### 1. Field of the Invention

The disclosure relates generally to the methods and apparatuses of fabricating solar cells. Specifically, the disclosure relates to the methods and apparatuses of manufacturing high-efficiency solar cells by decreasing contact resistance and forming point contacts.

### 2. Description of the Prior Art

In recent years, owing to the continuous consumption of natural resources such as petroleum and coal, as well as the rise in eco-consciousness, there has been a worldwide demand for alternative energy sources. In particular, solar cells have attracted lots of attention because they generate renewable energy through abundant sunlight. One type of the photovoltaic solar cells (hereinafter referred to as “solar cells”) takes advantage of semiconductor properties to convert light into electricity. The power characteristics of solar cells are typically determined by Equation 1.

$$η ( \% ) = \frac{FF \cdot {V}_{OC} \cdot {J}_{SC}}{{P}_{in} \cdot A} \qquad ( Eq . 1 )$$

Wherein n represents the power conversion efficiency, FF is the abbreviation for fill factor, V_{OC} represents the open-circuit voltage, J_{SC} represents the short-circuit current, Pᵢₙ represents the power density of light incident into the solar cell, and A represents the effective illuminated area of the solar cell.

The fill factor, expressed as Equation 2, is an important criterion to measure the output characteristics of solar cells. The larger the FF value is, the more power the solar cell can output.

$$FF = \frac{{P}_{max}}{{V}_{OC} \cdot {J}_{SC}} \qquad ( Eq . 2 )$$

Wherein FF is the abbreviation for fill factor, V_{OC} represents the open-circuit voltage, J_{SC} represents the short-circuit current, and Pₘₐₓ represents the maximum power density.

The FF is sensitive to the series and parallel resistance. An increase in series resistance or a decrease in parallel resistance results in a lower FF value. Increasing series resistance will result in low short-circuit current. The open-circuit voltage may decrease if the parallel resistance is not high enough. All of the above leads to insufficient conversion efficiency of solar cells.

Therefore, it is desirable to study the parameters such as open-circuit voltage, short-circuit current and FF to enhance the performance of solar cells and thus expand their utilizations.

### SUMMARY OF THE INVENTION

In view of the foregoing, one object of the invention is to provide methods of manufacturing high-efficiency solar cells, by which contact resistance is decreased and discrete point contacts are formed so that the carrier recombination is reduced, and the FF and open-circuit voltage are improved. Furthermore, apparatuses of manufacturing high-efficiency solar cells using the disclosed methods are provided.

According to one aspect of the invention, a method of manufacturing a point-contact solar cell is provided. The method comprises providing a silicon substrate with a metallic electrode disposed on a surface of the silicon substrate, applying a high-frequency pulsed voltage to the metallic electrode, and illuminating the silicon substrate using a laser at a power density of greater than 10 W/m² under the high-frequency pulsed voltage and then scanning the silicon substrate by the laser rapidly. The high-frequency pulsed voltage includes pulse-on time and pulse-off time, and has a frequency of about 1 kHz to 10 MHz and a duty cycle of about 5% to 95%. During the pulse-on time, the metallic electrode is subjected to the high-frequency pulsed voltage and the induced pulsed current while illuminated by the laser. Thereby thermal heat is generated to sinter and form a plurality of separate conductive regions in-situ at the interface between the silicon substrate and the metallic electrode.

According to another aspect of the invention, a method of manufacturing a point-contact solar cell is provided. The method comprises: providing a solar cell which includes a silicon substrate, an anti-reflective layer on the silicon substrate and a metallic electrode on the anti-reflective layer, applying a high-frequency pulsed voltage comprised of pulse-on time and pulse-off time to the solar cell using a pulsed power supply, and illuminating and scanning the solar cell using a laser at a power density of greater than 10 W/m² under the high-frequency pulsed voltage. The high-frequency pulsed voltage is a reverse bias voltage and is not less than the breakdown voltage of the solar cell. During the pulse-on time, photoelectric effect is induced along with illumination by the laser, generating locally high current and heat, and thus sintering through the anti-reflective layer beneath the metallic electrode subjected to the high-frequency pulsed voltage. The metal contained in the metallic electrode diffuses further into the silicon substrate and interacts with Si to form at least one conductive region at the exposed interface of the silicon substrate. During the pulse-off time, the anti-reflective layer beneath the metallic electrode is unaffected by the high-frequency pulsed voltage so the anti-reflective layer remains on the silicon substrate for passivation.

According to still another aspect of the invention, an apparatus of manufacturing a point-contact solar cell is provided. The apparatus comprises a carrying device configured to support a solar cell, a conducting module electrically connected to the solar cell optionally, a pulsed power supply used to provide a high-frequency pulsed voltage that is a reverse bias voltage and has a frequency of about 1 kHz to 10 MHz and a duty cycle of about 5% to 95%, and a light source. As the pulsed power supply applies the high-frequency pulsed voltage to the solar cell via the conducting module, the light source illuminates the solar cell at a power density of 10 W/m² above and scans the solar cell. Thereby a plurality of discontinuous conductive regions are formed in the solar cell.

Additional features and advantages of the disclosure will be set forth in the detailed description which follows, and in part will be readily apparent to those skilled in the art from that description or recognized by practicing the aspects as described herein, including the detailed description which follows, the claims, as well as the appended drawings.

It is to be understood that both the foregoing general description and the following detailed description are merely exemplary and are intended to provide an overview or framework for understanding the nature and character of the disclosure and claims. The accompanying drawings are included to provide a further understanding of the disclosure and are incorporated into and constitute a part of this specification. The drawings illustrate various aspects of the disclosure and together with the description serve to explain the principles and operations of the various aspects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically illustrates the structure of a solar cell.

FIG. 2 shows the partial cross-section cut along the line 2-2′ of FIG. 1.

FIG. 3 schematically illustrates a method of manufacturing a point-contact solar cell according g to one embodiment of the invention.

FIG. 4A and FIG. 4B schematically illustrate a method of manufacturing a point-contact solar cell according to another embodiment of the invention.

FIG. 5 schematically illustrates a method of manufacturing a point-contact solar cell according to another embodiment of the invention.

FIG. 6 shows the block diagram of an apparatus for manufacturing point-contact solar cells according to one embodiment of the invention.

FIG. 7A and FIG. 7B show the block diagram of an apparatus for manufacturing point-contact solar cells according to another embodiment of the invention.

### DETAILED DESCRIPTION

Reference will now be made in detail to various embodiments of the present invention, examples of which are illustrated in the accompanying drawings. Whenever possible, the same reference numerals will be used throughout the drawings to refer to the same or like parts. The drawings are not necessarily drawn to scale, nor are the (relative) sizes of components shown limited to those, emphasis instead being placed upon illustrating the representative embodiments.

Directional terms as used herein, for example up, down, right, left, front, back, top, bottom, are made only with reference to the figures as drawn and are not intended to imply absolute orientations.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it is to be understood that the particular value forms another embodiment. It will be further understood that the endpoints of each of the ranges are significant both in relation to the other endpoint, and independently of the other endpoint.

FIG. 1 schematically illustrates the structure of a solar cell. The solar cell 100 generally includes a silicon substrate 110, an electrode 120 disposed on the front (e.g., the light-receiving surface) of the silicon substrate 110, an electrode 180 disposed on the back of the silicon substrate 110, an anti-reflective layer 130 disposed between the front electrode 120 and the silicon substrate 110, and a passivation layer 190 disposed between the back electrode 180 and the silicon substrate 110. An emitter layer 112 is disposed on the light-receiving side of the silicon substrate 110. As an example, the silicon substrate 110 is an n-type substrate and the emitter layer 112 is a p-doped emitter, both of which constitute the p/n junction. The electrode 120 typically includes multiple fingers 127 and bus bars 129. The fingers 127 and the bus bars 129 are electrically connected and are substantially orthogonal to each other. To avoid obscuring the disclosure, the arrangements and other features of the electrode will not be detailed.

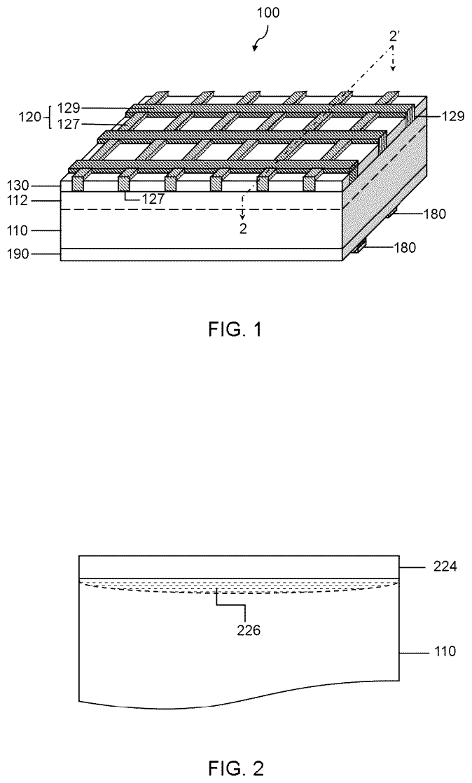

Currently, the formation of the electrode 120 is mainly based on the screen printing technology, where conductive paste is applied to the surface of the silicon substrate 110. Traditionally, as shown in FIG. 2, the applied conductive paste is then fired at high temperature to form an electrode layer 224. The metal atoms of the conductive paste are further sintered to combine with the silicon atoms from the surface of the silicon substrate to form a conductive region 226 and thus an electrode with reduced contact resistance. However, such a firing process has to be performed at peak temperature (i.e. the highest temperature during the process), generally at about 800° C. or above. On the other hand, if the time for firing at high temperature is too long, defects are produced due to over-firing, resulting in low open-circuit voltage and even damaging the performance of solar cells. Overall, it is not easy to control the process.

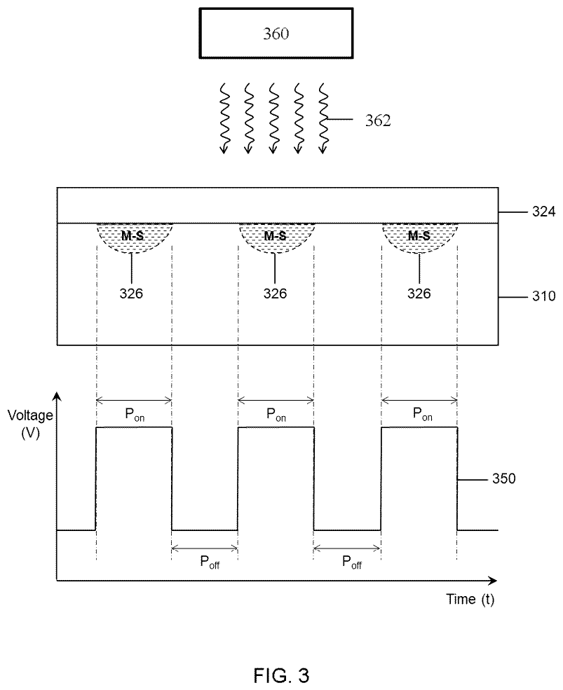

Referring to FIG. 3, which schematically illustrates a method of manufacturing a point-contact solar cell according to one embodiment of the invention. The method includes providing a silicon substrate 310. A metallic layer 324 is disposed on the surface of the silicon substrate 310. Alternatively, the silicon substrate 310 may be replaced with another semiconductor substrate with a p/n junction. The metallic layer 324 is formed, for example, by the application of conductive paste and metallization. The methods of application include, but not limited to, spraying, screen printing, transfer printing, etc. The composition of the metallic layer may depend on the composition of the conductive paste. Generally, the conductive paste may comprise metal, glass frit and binders (organic compounds). In one embodiment, the metallic layer and the resultant electrode comprise metal and glass frit. The contained metal may be, for example, silver (Ag), aluminum (Al), copper (Cu), nickel (Ni), an alloy thereof, or a combination thereof. The glass frit may be, for example, lead-containing glass frit, silica-containing glass frit, bismuth-containing glass frit, or a combination thereof. In the disclosure, after the conductive paste is applied, metallization is performed at a temperature used to burn off the binder and melt the glass frit of the conductive paste. The selected temperature is less than the conventional firing temperature, e.g., about 20-200° C. lower. In the description hereinafter, for illustration and explanation, the fired metallic layer is referred to as the “metallic electrode” 324. Since a relatively low temperature is utilized at this step, it is expected that fewer defects are produced in solar cells, and the power conversion efficiency is improved.

Still referring to FIG. 3, a high-frequency pulsed voltage 350 is applied to the metallic electrode 324 by a pulsed power supply, for example. The frequency of the high-frequency pulsed voltage may be about 1 kHz to 10 MHz. When the frequency of the high-frequency pulsed voltage exceeds 10 MHz, too many point contacts may be formed per unit of time, potentially resulting in a continuous strip of contact. In this case, although the contact impedance of the continuous strip is low, the defect density causing recombination loss increases, which is unfavorable for conversion efficiency. In contrast, when the frequency of the high-frequency pulsed voltage is lower than 1 kHz, too few point contacts may be formed per unit of time. In this case, although the defect density causing recombination loss is low, the contact impedance of the point contacts increases, which is also unfavorable for conversion efficiency. The duty cycle of the high-frequency pulsed voltage may be about 5% to 95%. When the duty cycle of the high-frequency pulsed voltage exceeds 95%, too many point contacts may be formed in the corresponding firing process, potentially resulting in a continuous strip of contact. In this case, although the contact impedance of the continuous strip is low, the defect density causing recombination loss increases, which is unfavorable for conversion efficiency. In contrast, when the duty cycle of the high-frequency pulsed voltage is lower than 5%, too few point contacts may be formed in the corresponding firing process. In this case, although the defect density causing recombination loss is low, the contact impedance of the point contacts increases, which is also unfavorable for conversion efficiency. In one embodiment, the high-frequency pulsed voltage is a reverse bias voltage and is typically less than the breakdown voltage of the solar cell. For example, the high-frequency pulsed voltage is about 50%-99% of the breakdown voltage. In another embodiment of the invention, the high frequency pulsed voltage is a reverse bias voltage not less than the breakdown voltage of the solar cell, which will be described in further detail below. In this case, the high-frequency pulsed voltage is preferably 100%-150% of the breakdown voltage. When the high-frequency pulsed voltage exceeds 150% of the breakdown voltage, the p/n junction of the solar cell is likely to be damaged by the high voltage, thereby degrading the electrical performance of the solar cell. In one embodiment, because the reverse bias voltage applied to the solar cell is a high-frequency pulsed voltage with a frequency of about 1 kHz to 10 MHz and a duty cycle of about 5% to 95%, the electrical performance of the solar cell is not degraded even if the high-frequency pulsed voltage exceeds the breakdown voltage of the solar cell. Furthermore, because the high-frequency pulsed voltage exceeds the breakdown voltage of the solar cell, the diffusion process of the metallic atoms can be carried out more efficiently without generating defects in the solar cell, or with minimal defects. Next, a light source 360 which is configured to generate light 362 is used to illuminate the area adjacent to the metallic electrode 324, and scan it rapidly. In one embodiment, the light source 360 is a laser device, and the light 362 is a laser. The laser spot of the light 362 may be round, square, rectangular, or other shaped. In one embodiment, the power density of the light 360 is greater than about 10 W/m² as long as the structure of the solar cell is not damaged by the light 360. When power density of the light 360 is lower than 10 W/m², even though the high-frequency pulsed reverse bias voltage is applied to the solar cell, no conductive point contacts are generated. The light source 360 may illuminate and scan a predetermined region (e.g., the area adjacent to the electrode) of the substrate or scan the semiconductor substrate entirely.

No function will occur during the pulse-off time (“P_{off}” in FIG. 3) even if a high-frequency pulsed voltage is applied. However, during the pulse-on time (“Pₒₙ” in FIG. 3), a high-frequency pulsed current results from the photoelectric effect induced by photons from the light 360 under the applied high-frequency pulsed voltage, causing the metal atoms (M) in the corresponding portion of the metallic electrode 324, which are subjected to the heat generated by the pulsed voltage, to inter-diffuse with the silicon atoms(S) near the surface of the silicon substrate 310 and combine with each other (M-S) at the interface. Hence a plurality of separate conductive regions 326 are formed in-situ. Compared to the conductive region 226 in FIG. 2, the conductive regions 326 thus formed include multiple discontinuous point contacts. The number and spacing of the conductive regions may vary as desired, and can be adjusted by e.g., modulating the pulse-on/pulse-off time or changing the scanning speed of the light source. The position and size of the conductive regions can be defined by the scanning position and spot size of the light source, and so forth.

According to one embodiment of the invention, a method of manufacturing a point-contact solar cell includes providing a silicon (Si) wafer (e.g., the silicon substrate 310) and forming an electrode on the Si wafer. The method of forming an electrode includes using conductive silver paste and firing at a temperature of e.g., about 40° C. lower than the conventional firing temperature to form a metallic electrode (e.g., the metallic electrode 324). The metallic electrode includes a mixture of silver (Ag) and glass frit. A laser (e.g., the light 340) is used to scan in the vicinity of the metallic electrode while a high-frequency pulsed reverse bias voltage (e.g., the high-frequency pulsed voltage 350) is applied. The reverse bias voltage is less than the breakdown voltage of the cell, and preferably is about 50%-99% of the breakdown voltage. Preferably, the power density of the laser is above about 10 W/m². The frequency of the high-frequency pulsed voltage is about 1 kHz to 10 MHz, and the duty cycle is about 5% to 95%. In this case, during the pulse-on time for the pulsed voltage, the laser photons generate additional pulsed reverse bias voltage induced current at the position where the voltage is applied, causing Ag to diffuse into the silicon wafer and Si to diffuse into the metallic electrode. Ag and Si combine at the interface between the silicon wafer and the metallic electrode to form a plurality of separate Ag—Si conductive regions (e.g., the conductive regions 326) as conducting channels. In this embodiment, the implementation of laser-assisted firing lowers the peak firing temperature at the firing step, and thus fewer defects are produced. Furthermore, separate conductive regions with low contact resistance are formed at the interface between the electrode and the silicon wafer by laser scanning under the high-frequency pulsed voltage. This process not only decreases the contact resistance and increases the FF, but also forms the discontinuous point-contacts, reduces the carrier recombination, and improves the open-circuit voltage and short-circuit current, thereby enhancing the overall conversion efficiency of the solar cell.

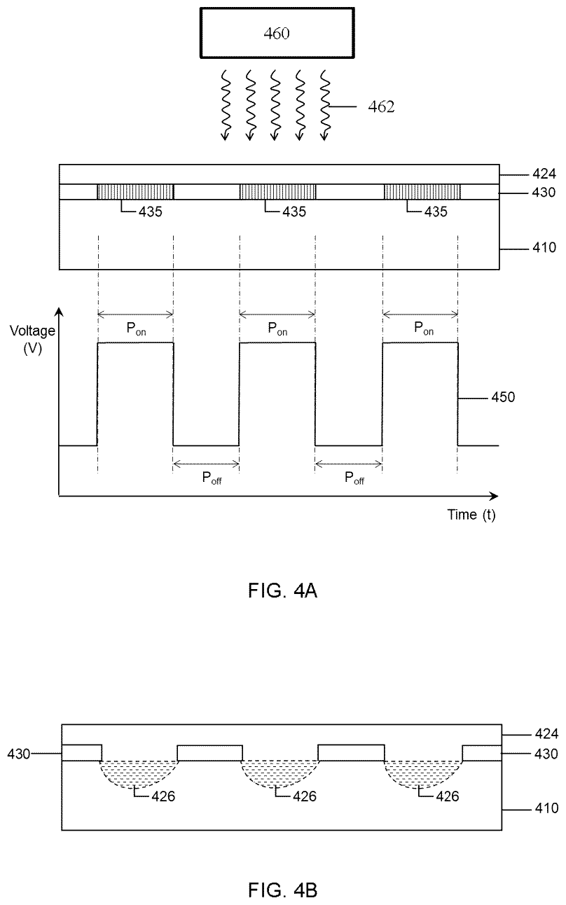

FIG. 4A and FIG. 4B schematically illustrate a method of manufacturing a point-contact solar cell according to another embodiment of the invention. The method in FIG. 4A through FIG. 4B is similar to that aforementioned in FIG. 3, except that an anti-reflective layer 430 is disposed between the surface of the silicon substrate 410 and the metallic electrode 424. The anti-reflective layer 430 is typically a silicon nitride (SiNₓ) layer. The details relevant to the silicon substrate 410 are similar to those of the silicon substrate 310 in FIG. 3; and the metallic electrode 424 is formed in the same manner as the metallic electrode 324 shown in FIG. 3; these will not be itemized herein. Then, a pulsed power supply is used to provide a high-frequency pulsed voltage 450 to the metallic electrode 424. The frequency of the high-frequency pulsed voltage may be about 1 kHz to 10 MHz, and the duty cycle may be about 5% to 95%. In this embodiment, the high-frequency pulsed voltage is equal to or greater than the breakdown voltage of the solar cell, and is preferably a reverse bias voltage not less than the breakdown voltage. For example, the high-frequency pulsed voltage is about 100%-150% of the breakdown voltage. A light source 460 which is configured to generate a light 462 is used to illuminate and scan the area adjacent to the metallic electrode 424 when the high-frequency pulsed voltage is applied. The power density of the light may be greater than about 10 W/m². The types and illumination characteristics of the light 460 are similar to those of the light 360 in FIG. 3, and will not be detailed herein. Under the applied high-frequency pulsed voltage (corresponding to the pulse-on time “Pₒₙ”), photons from the light source locally induce photoelectric effect and generate an extra pulsed reverse-bias voltage-induced current, which drives the metal atoms of the metallic electrode 424 to move toward the silicon substrate 410, triggering the sintering reaction and thus reducing the contact resistance. If the high-frequency pulsed voltage is equal to or greater than the breakdown voltage, more local current and heat will be generated for sintering through the anti-reflective layer 435 (shown in FIG. 4A). The wavelength of the photons from the light source may range from 300 to 1200 nm, but is not limited thereto, as long as the photons can induce the photoelectric effect in the silicon substrate 410. The metal atoms diffuse further into the silicon substrate 410 via the sintered-through anti-reflective layer 435, thereby forming the conductive regions 426 at the exposed interface of the silicon substrate 410. The intensity of high-frequency pulsed voltage may depend on the thickness of the layer to be sintered through. As mentioned above, no function occurs during the pulse-off time. As shown in FIG. 4B, during the pulse-on time “Pₒₙ”, the anti-reflective layer 435 beneath the metallic electrode 424 subjected to the pulsed voltage is sintered through, and the conductive regions 426 are formed thereafter. During the pulse-off time “P_{off}”, no photoelectric effect is induced so the anti-reflective layer 430 beneath the metallic electrode 424 remains intact. The discontinuous point-contact structures thus formed benefit low contact resistance and FF improvement. Moreover, retaining part of the anti-reflective layer is advantageous for surface passivation. These contribute to fewer recombination defects at the interface and increased open-circuit voltage, thereby improving the power conversion efficiency of the solar cell.

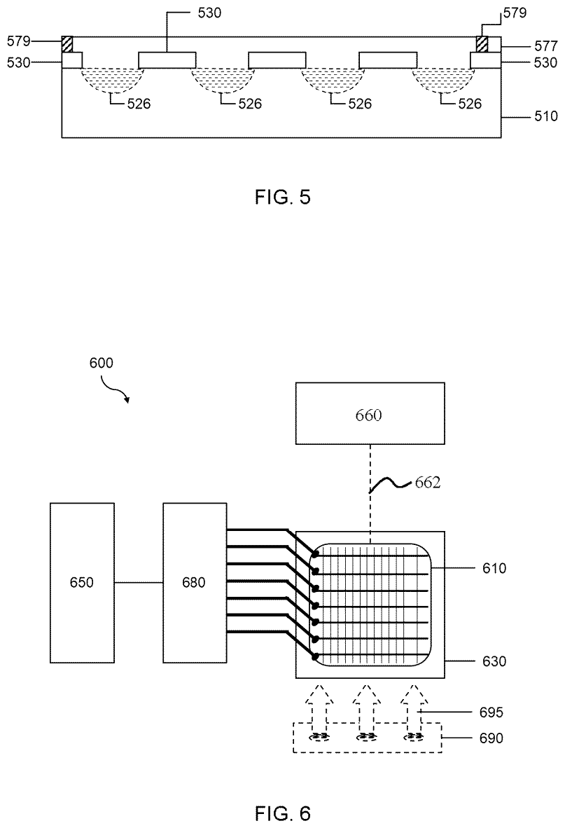

According to one embodiment of the invention, a method of manufacturing a point-contact solar cell includes providing a solar cell. Referring to FIG. 5, the solar cell includes a silicon wafer 510, a layer of silicon nitride 530 on the silicon wafer 510 and a plurality of fingers 577 and bus bars 579 on the silicon nitride layer 530. The fingers 577 and the bus bars 579 are connected to each other in a grid arrangement. In one embodiment, the fingers 577 and the bus bars 579 are composed of a mixture of silver and glass frit. The method further includes using a laser (e.g., the light 460) to scan the area adjacent to the electrode arrangement (e.g., the fingers 577), and applying a high-frequency pulsed reverse-bias voltage (e.g., the high-frequency pulsed voltage 450) to the solar cell by a pulsed power supply. The reverse bias voltage is not less than the breakdown voltage of the cell and is preferably about 100%-150% of the breakdown voltage. The power density of the laser is preferably greater than about 10 W/m². The high-frequency pulsed voltage has a frequency of about 1 kHz to 10 MHz and a duty cycle of about 5% to 95%. Because the reverse bias voltage is equal to or greater than the breakdown voltage of the solar cell, laser photons affected by the pulse-on voltage cause Ag in the portion of the fingers 577 to move toward the silicon wafer 510, and generate high current and heat locally, facilitating sintering through the silicon nitride layer 530. Subsequently, Ag diffuses into the silicon wafer 510 and combines with Si to form a plurality of separate Ag—Si conductive regions 526 at the exposed interface of the silicon wafer 510. Meanwhile, during the pulse-off time (e.g., “P_{off}” in FIG. 4A), the silicon nitride layer 530 beneath the unaffected fingers 577 and the bus bars 579 is retained for surface passivation. In this embodiment, performing laser scanning concurrent with applying a high-frequency pulsed voltage not less than the breakdown voltage can form discontinuous point-contact structures and retain part of the silicon nitride layer. The point-contact structures and the retained silicon nitride layer may decrease the contact resistance, reduce the recombination defects and increase the open-circuit voltage, thereby improving the conversion efficiency of solar cells.

FIG. 6 shows the block diagram of an apparatus for manufacturing point-contact solar cells according to one embodiment of the invention. The apparatus 600 includes a carrying device 630, a power supply 650, a light source 660 which is configure to generate light 662, and a conducting module 680. The carrying device 630 is configured to support a solar cell 610. The conducting module 680 is electrically connected to the electrode of the solar cell 610 to provide conducting channels. The power supply 650 is configured to apply a high-frequency pulsed voltage to the solar cell 610 via the conducting module 680. In one embodiment, the power supply 650 is a pulsed power supply, which can provide a high-frequency pulsed voltage with a frequency of about 1 kHz to 10 MHz and a duty cycle of about 5% to 95% to the solar cell. The light source 660 is configured to illuminate and scan the solar cell 610 with the light 662. In one embodiment, the light 660 is a laser. The laser spot may be round, square, rectangular, or other shaped. The light source 660 may project a power density of over 10 W/m² onto the solar cell 610. In addition, the light source 660 may scan a portion or the entirety of the solar cell 610.

In another embodiment, the apparatus 600 further comprises a cooling device 690 disposed under the carrying device 630. The cooling device 690 is used to dissipate heat from the solar cell 610 or the carrying device 630, preventing damage to the solar cells. It is to be understood that the cooling device 690 may be disposed in any position other than under the carrying device, as long as effective cooling is achieved. The cooling device 690 may be a gas-cooled cooler, which dissipates heat during processing by flowing gas, for example, by supplying cooling gas 695 (e.g., air). Alternatively, the cooling device may be a liquid-cooled cooler (not shown) that cools the solar cell or the carrying device by flowing liquid.

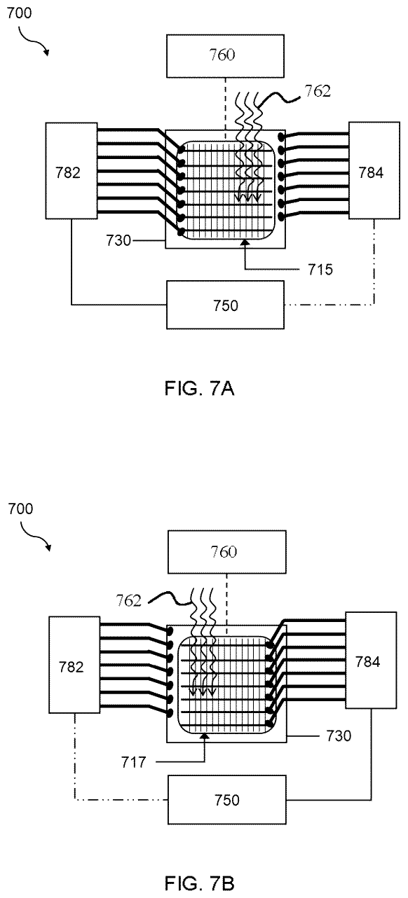

There are no restrictions on the number and arrangements of various components in the disclosure. As an example, the disclosed apparatus may include one or more light sources and/or one or more conducting modules to perform different scanning operation (e.g., multiple successive scans). FIG. 7A through FIG. 7B show the block diagram of an apparatus equipped with two conducting modules according to another embodiment of the invention. The apparatus 700 comprises a carrying device 730 for supporting a solar cell, two conducting modules 782, 784 for providing conducting channels optionally, a power supply 750 for applying a high-frequency pulsed voltage via the conducting modules 782 or 784, and a light source 760 for illuminating and scanning the solar cell with light 762. For multiple scans, as shown in FIG. 7A, the power supply 750 applies a high-frequency pulsed voltage via the first conducting module 782 to the solar cell placed on the carrying device 730. Meantime the light source 760 illuminates and scans the portion 715 of the solar cell unobstructed by the conducting module 782 (the right side of the figure). As shown in FIG. 7B, then the second conductive module 784 is brought into contact with the scanned portion 715 of the solar cell, and the light source 760 scans the portion 717 of the solar cell not scanned yet (the left side of the figure) to achieve a complete scanning. This ensures scanning the whole solar cell and thus improves its effective utilization.

The configurations and operating conditions of the carrying device 730, the conducting modules 782, 784, the power supply 750, and the light source 760 depicted in FIG. 7A and FIG. 7B are similar to those of the carrying device 630, the conducting module 680, the power supply 650, and the light source 660 depicted in FIG. 6, and will not be detailed herein respectively.

According to one embodiment, the apparatuses disclosed herein are configured to implement the method of manufacturing a solar cell in accordance with the embodiment of FIG. 3. According to another embodiment, the apparatuses disclosed herein are configured to implement the method of manufacturing a solar cell in accordance with the embodiment of FIG. 4A and FIG. 4B. According to still another embodiment, the apparatuses disclosed herein are configured to implement the method of manufacturing a solar cell in accordance with the embodiment of FIG. 5.

By using the methods and apparatuses described herein to fabricate point-contact solar cells, the solar cells may be manufactured at a relatively low firing temperature, with fewer defects, and may also form discontinuous conductive regions with lower contact resistance. Moreover, the anti-reflective layer may be retained for surface passivation as desired. As a result, carrier recombination is reduced, and the FF and open-circuit voltage are increased, facilitating an improvement in the conversion efficiency of solar cells.

While various features, elements or steps of particular aspects or embodiments may be disclosed using the transitional phrase “comprising”, it is to be understood that alternative aspects or embodiments, including those that may be described using the transitional phrases “consisting of” or “consisting essentially of,” are implied. Thus, for example, implied alternative aspects or embodiments to a device that comprises A+B+C include aspects or embodiments where a device consists of A+B+C and aspects or embodiments where a device consists essentially of A+B+C.

It will be apparent to those skilled in the art that various modifications and variations can be made to the present disclosure without departing from the spirit and scope of the invention. Since modifications combinations, sub-combinations, and variations of the disclosed embodiments incorporating the spirit and substance of the disclosure may occur to persons ordinarily skilled in the art, the invention should be construed to include everything within the scope of the appended claims and their equivalents.

Those skilled in the art will readily observe that numerous modifications and alterations of the device and method may be made while retaining the teachings of the invention. Accordingly, the above disclosure should be construed as limited only by the metes and bounds of the appended claims

What is claimed is:

1. An apparatus of manufacturing a point-contact solar cell, comprising:
a carrying device configured to support a solar cell;
a conducting module configured to be electrically connected to the solar cell;
a pulsed power supply configured to provide a high-frequency pulsed voltage, wherein the high-frequency pulsed voltage is a reverse bias voltage and has a frequency of about 1 kHz to 10 MHz and a duty cycle of about 5% to 95%; and
a light source configured to generate a light,
wherein, as the pulsed power supply applies the high-frequency pulsed voltage to the solar cell via the conducting module, the light source illuminates and scans a surface of the solar cell at a power density of 10 W/m², thereby forming a plurality of discontinuous conductive regions in the solar cell.

2. The apparatus of claim 1, wherein the high-frequency pulsed voltage is a reverse bias voltage being 50%-99% of a breakdown voltage of the solar cell.

3. The apparatus of claim 1, wherein the high-frequency pulsed voltage is not less than a breakdown voltage of the solar cell.

4. The apparatus of claim 3, wherein the high-frequency pulsed voltage is a reverse bias voltage being 100%-150% of a breakdown voltage of the solar cell.

5. The apparatus of claim 1, wherein the light source is a laser device.

6. The apparatus of claim 1, further comprising a cooling device configured to dissipate heat from the solar cell or the carrying device.

7. The apparatus of claim 6, wherein the cooling device is a cooling device using gas or liquid flow.
